(19) United States
(12) Patent Application Publication
(10) Pub. No.: US 2025/0318219 A1
(43) Pub. Date: Oct. 9, 2025

(54) SEMICONDUCTOR DEVICE

(71) Applicant: Samsung Electronics Co., Ltd., Suwon-si (KR)

(72) Inventors: Bumcheol KIM, Suwon-si (KR); Wookhyun KWON, Suwon-si (KR); Hyunmin AHN, Suwon-si (KR); Soojin JEONG, Suwon-si (KR); Byoung Hak HONG, Suwon-si (KR)

(73) Assignee: Samsung Electronics Co., Ltd., Suwon-si (KR)

(21) Appl. No.: 18/890,099

(22) Filed: Sep. 19, 2024

(30) Foreign Application Priority Data
Apr. 5, 2024 (KR) 10-2024-0046513

(51) Int. Cl. H01L 29/06; H01L 29/08; H01L 29/423; H01L 29/775; H01L 29/786

(52) U.S. Cl. CPC H10D 62/121; H10D 30/43; H10D 30/6735; H10D 30/6757; H10D 62/151

(57) ABSTRACT

A semiconductor device comprising, a substrate, an active pattern on the substrate, the active pattern including a plurality of channel patterns spaced apart from each other and vertically stacked on each other, a source/drain pattern on at least one side of the plurality of channel patterns, a gate electrode surrounding the plurality of channel patterns, the gate electrode including a lower gate electrode between adjacent channel patterns of the plurality of channel patterns, an insulating film structure between the gate electrode and the plurality of channel patterns, and an inner gate spacer between the source/drain pattern and the lower gate electrode, wherein a sidewall of the insulating film structure is between the source/drain pattern and the inner gate spacer.

### CROSS-REFERENCE TO RELATED APPLICATION

This application claims benefit of and priority to Korean Patent Application No. 10-2024-0046513, filed in the Korean Intellectual Property Office on Apr. 5, 2024, the entire contents of which are hereby incorporated by reference.

### BACKGROUND

The present disclosure relates to a semiconductor device.

A semiconductor device is a core component used to control or amplify an electrical signal in an electronic device, and various types of semiconductor devices may be manufactured. For example, a memory device may be mainly used to store and retrieve data, while a non-memory device may be used to control or amplify an electrical signal. The semiconductor device is a core component of an electronic device and plays an important role in various fields including computers, communication equipment, consumer electronics, etc.

With the development of industry, the performance and function requirements of the electronic devices are also increasing. Accordingly high-performance characteristics of the semiconductor devices are essentially required, and the degree of integration of the semiconductor devices is increasing to meet these requirements. Various methods for forming semiconductor devices having excellent performance and improved degree of integration are being studied.

### SUMMARY

In order to solve one or more problems (e.g., the problems described above and/or other problems not explicitly described herein), the present disclosure may provide a semiconductor device with improved electrical characteristics and reliability.

According to some example embodiments of the present disclosure, a semiconductor device may include, a substrate, an active pattern on the substrate, the active pattern including a plurality of channel patterns spaced apart from each other and vertically stacked on each other, a source/drain pattern on at least one side of the plurality of channel patterns, a gate electrode surrounding the plurality of channel patterns, the gate electrode including a lower gate electrode between adjacent channel patterns of the plurality of channel patterns, an insulating film structure between the gate electrode and the plurality of channel patterns, and an inner gate spacer between the source/drain pattern and the lower gate electrode, wherein a sidewall of the insulating film structure is between the source/drain pattern and the inner gate spacer.

According to some example embodiments of the present disclosure, a semiconductor device may include, a substrate, an active pattern extending in a first direction, the active pattern including a lower pattern disposed on the substrate and a plurality of channel patterns spaced apart in a second direction perpendicular to the first direction, a source/drain pattern on at least one side of the plurality of channel patterns, a gate electrode surrounding the plurality of channel patterns and extending in a third direction crossing the second direction, the gate electrode including an upper gate electrode on the plurality of channel patterns, and a lower gate electrode between adjacent channel patterns of the plurality of channel patterns, an insulating film structure between the gate electrode and the plurality of channel patterns and between the gate electrode and the source/drain pattern, and an inner gate spacer extending in the third direction and between the lower gate electrode and the source/drain pattern, wherein the insulating film structure is between an upper surface of the inner gate spacer and the plurality of channel patterns.

According to some example embodiments of the present disclosure, a semiconductor device may include a substrate, an active pattern extending in a first direction, the active pattern including a lower pattern disposed on the substrate and a plurality of channel patterns spaced apart in a second direction perpendicular to the first direction, a source/drain pattern on at least one side of the plurality of channel patterns, a gate electrode surrounding the plurality of channel patterns, the gate electrode including an upper gate electrode on the plurality of channel patterns, and a lower gate electrode between adjacent channel patterns of the plurality of channel patterns, a gate spacer on one side of the upper gate electrode, an insulating film structure between the gate electrode and the plurality of channel patterns, the insulating film structure including an interfacial insulating film on the plurality of channel patterns and a high dielectric constant insulating film on the interfacial insulating film, and an inner gate spacer between the insulating film structure and the lower gate electrode, wherein a sidewall of the insulating film structure is between the source/drain pattern and the inner gate spacer, and the high dielectric constant insulating film is in contact with an upper surface, a lower surface, and a side surface of the inner gate spacer, respectively.

According to some example embodiments of the present disclosure, because the inner gate spacer is disposed between the gate electrode and the source/drain pattern, the capacitance value between the gate electrode and the source/drain pattern may be reduced. Accordingly, the performance of the semiconductor device may be improved.

According to some example embodiments of the present disclosure, the insulating film structure is disposed between the inner gate spacer and the channel pattern, thereby preventing or reducing in likelihood the constituent material of the inner gate spacer from diffusing into the channel pattern. Accordingly, the reliability of the semiconductor device may be improved.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view provided to explain a semiconductor device according to some example embodiments of the present disclosure;

FIG. 2 is a cross-sectional view taken along line A-A of FIG. 1;

FIGS. 3 and 4 are enlarged views provided to explain a region R1 of FIG. 2;

FIG. 5 is a cross-sectional view taken along line B-B of FIG. 1;

FIG. 6 is a diagram illustrating a semiconductor device according to some example embodiments of the present disclosure;

FIG. 7 is a diagram illustrating a semiconductor device according to some example embodiments of the present disclosure;

FIG. 8 is a diagram illustrating a semiconductor device according to some example embodiments of the present disclosure;

FIG. 9 is a diagram illustrating a semiconductor device according to some example embodiments of the present disclosure;

FIGS. 10 and 11 are enlarged views provided to explain a region R2 of FIG. 9;

FIGS. 12 to 30 are diagrams showing intermediate stages, provided to explain some methods for manufacturing semiconductor devices according to some example embodiments of the present disclosure.

### DETAILED DESCRIPTION

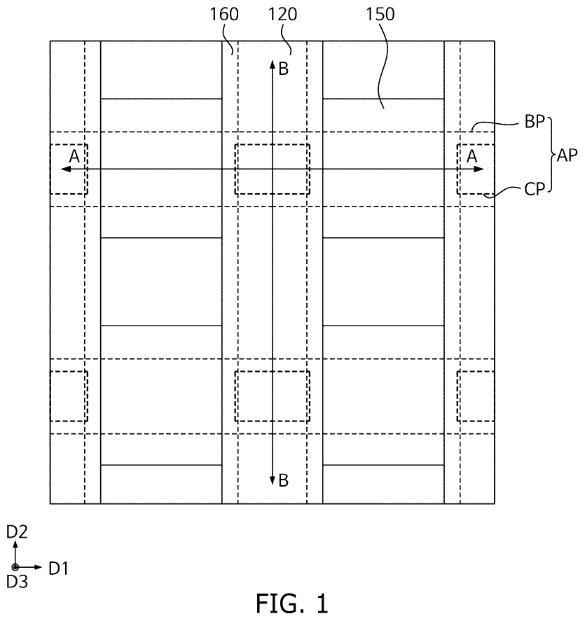

A semiconductor device according to some example embodiments of the present disclosure will be described with reference to FIGS. 1 to 5.

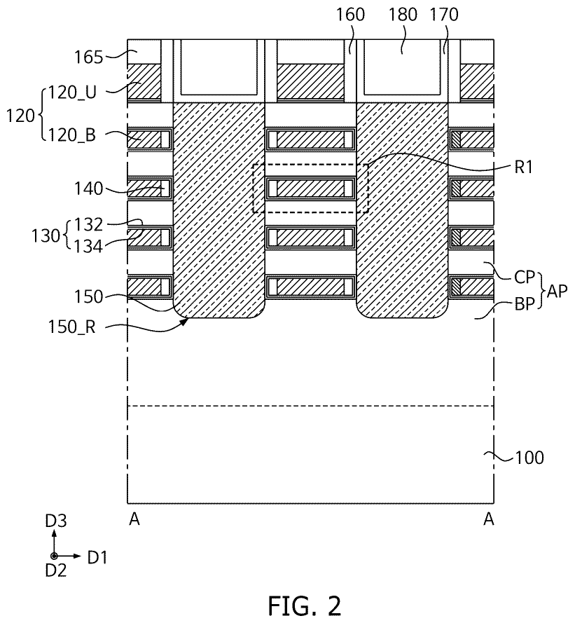

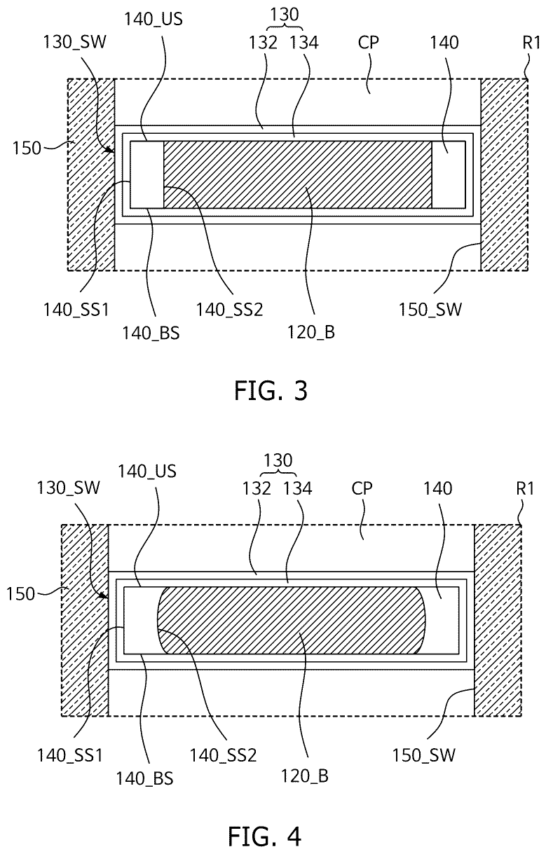

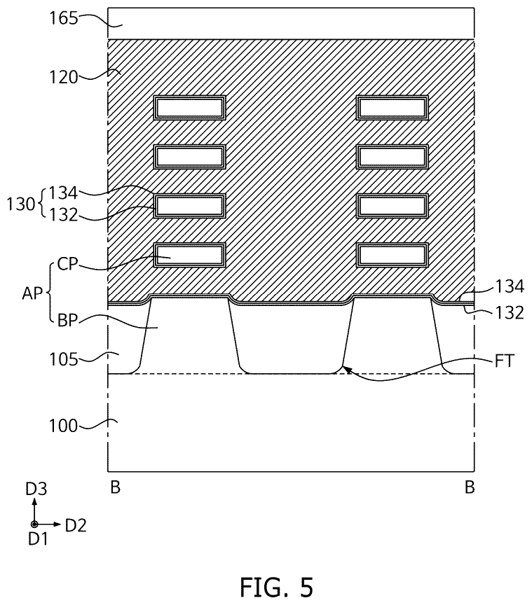

FIG. 1 is a plan view provided to explain a semiconductor device according to some example embodiments of the present disclosure. FIG. 2 is a cross-sectional view taken along line A-A of FIG. 1. FIGS. 3 and 4 are enlarged views provided to explain a region R1 of FIG. 2. FIG. 5 is a cross-sectional view taken along line B-B of FIG. 1.

Referring to FIGS. 1 to 5, a semiconductor device according to some example embodiments may include a substrate 100, an active pattern AP, a gate electrode 120, an insulating film structure 130, an inner gate spacer 140, a source/drain pattern 150, and a gate spacer 160.

A semiconductor device according to some example embodiments may include a MOSFET, and more specifically, may include a gate-all-round (GAA) transistor and a three-dimensional multi-stack semiconductor device referred to as a multi-bridge channel FET (MBCFET).

The substrate 100 may be a bulk silicon or a silicon-on-insulator (SOI). On the other hand, the substrate 100 may include silicon germanium (SiGe), silicon germanium on insulator (SGOI), indium antimony, lead tellurium compound, indium arsenic, indium phosphide, gallium arsenic, or gallium antimony, but is not limited thereto.

The active pattern AP may be disposed on the substrate 100. The active pattern AP may extend in a first direction D1. The active pattern AP may be spaced apart from the adjacent active pattern AP in a second direction D2. In this case, the first direction D1 is a direction crossing the second direction D2. Each of the first and second directions D1 and D2 may be a direction parallel to an upper surface of the substrate 100. The active pattern AP may be disposed in a region where a PMOS is formed. In another aspect, the active pattern AP may be disposed in a region where an NMOS is formed.

The active pattern AP may be a multi-channel active pattern. The active pattern AP may include a lower pattern BP and a plurality of channel patterns CP.

The lower pattern BP may protrude from the substrate 100. The lower pattern BP may extend in the first direction D1. The lower pattern BP may be spaced apart from the adjacent lower pattern BP in the second direction D2. The lower pattern BP adjacent to the lower pattern BP may be separated by a field trench FT. The field trench FT may be defined by the upper surface of the substrate 100 and a side surface of the lower pattern BP.

A plurality of channel patterns CP may be disposed on the lower pattern BP. A plurality of channel patterns CP may be spaced apart from the lower pattern BP in a third direction D3. Each of the channel patterns CP may be spaced apart from each other in the third direction D3. The third direction D3 may be a direction crossing each of the first and second directions D1 and D2. The third direction D3 may be a direction perpendicular to the upper surface of the substrate 100. The third direction D3 may be a thickness direction of the substrate 100. The channel pattern CP may have a nanosheet shape. Although it is illustrated that there are four channel patterns CP, aspects are not limited thereto.

The lower pattern BP may be formed by etching a part of the substrate 100. However, aspects are not limited thereto. For example, the lower pattern BP may include an epitaxial layer grown from the substrate 100. The lower pattern BP may include an element semiconductor material such as silicon (Si) or germanium (Ge). In addition, the lower pattern BP may include a compound semiconductor. For example, the lower pattern BP may include a group IV-IV compound semiconductor or a group III-V compound semiconductor.

For example, the group IV-IV compound semiconductor may be a binary compound or a ternary compound including at least two of carbon (C), silicon (Si), germanium (Ge), and/or tin (Sn).

For example, the group III-V compound semiconductor may be one of a binary compound, a ternary compound, or a quaternary compound formed by a combination of at least one of aluminum (Al), gallium (Ga), and/or indium (In) as a group III element and one of phosphorus (P), arsenic (As), and/or antimony (Sb) as a group V element.

The channel pattern CP may include one of an element semiconductor material such as silicon (Si) or silicon germanium (SiGe), a group IV-IV compound semiconductor, or a group III-V compound semiconductor. Each of the plurality of channel patterns CP may include the same material as the lower pattern BP, or may include a material different from the lower pattern BP.

The lower pattern BP and the plurality of channel patterns CP may include silicon (Si). In another aspect, the lower pattern BP and the plurality of channel patterns CP may include silicon germanium (SiGe). In another aspect, the lower pattern BP may include silicon (Si), and the plurality of channel patterns CP may include silicon germanium (SiGe).

A field insulating film 105 may be disposed on the substrate 100. The field insulating film 105 may fill a part of the field trench FT. The field insulating film 105 may be disposed between lower patterns BP adjacent to each other. The field insulating film 105 may extend in the first direction D1. The field insulating film 105 may be formed on the upper surface of the substrate 100. The field insulating film 105 may cover a part of a sidewall of the lower pattern BP. For example, as illustrated in FIG. 5, the field insulating film 105 may cover the sidewall of the lower pattern BP, but may not be disposed on the upper surface of the lower pattern BP. In other words, the field insulating film 105 may not be disposed between the upper surface of the lower pattern BP and the channel pattern CP.

For example, the field insulating film 105 may include an oxide, a nitride, a nitride oxide, or a combination thereof. Although it is illustrated that the field insulating film 105 is a single film, it is only for convenience of description, and aspects are not limited thereto. For example, the field insulating film 105 may be formed of a plurality of films.

The source/drain pattern 150 may be disposed in a source/drain trench 150_R extending in the third direction D3. The source/drain pattern 150 may fill the source/drain trench 150_R. The lower surface of the source/drain trench 150_R may be defined by the lower pattern BP. A side surface of the source/drain trench 150_R may be defined by the lower pattern BP, the channel pattern CP, and a sidewall 130_SW of the insulating film structure 130.

The source/drain pattern 150 may be disposed on the active pattern AP. The source/drain pattern 150 may be disposed on the lower pattern BP. The source/drain pattern 150 may be connected to the channel pattern CP. A part of a sidewall 150_SW of the source/drain pattern 150 may be in contact with the channel patterns CP. Another part of the source/drain pattern 150 may be in contact with the sidewall 130_SW of the insulating film structure 130. The source/drain pattern 150 may connect the channel patterns CP that are spaced apart from each other in the first direction D1. The source/drain pattern 150 may be disposed between the channel patterns CP that are spaced apart from each other in the first direction D1.

The source/drain pattern 150 may be disposed on at least one side of the gate electrode 120. The source/drain pattern 150 may be disposed between the adjacent gate electrodes 120 in the first direction D1. For example, the source/drain patterns 150 may be disposed on both sides spaced apart in the first direction D1 of a lower gate electrode 120_B. Unlike the illustration, the source/drain pattern 150 may be disposed on one side of the gate electrode 120 and may not be disposed on the other side of the gate electrode 120.

The source/drain pattern 150 may be an epitaxial pattern formed by a selective epitaxial growth process using the active pattern AP as a seed. The source/drain pattern 150 may serve as a source and a drain of the transistor that uses the channel pattern CP as a channel region.

The source/drain pattern 150 may include a semiconductor material. For example, the source/drain pattern 150 may include an element semiconductor material such as silicon (Si) or germanium (Ge). In addition, the source/drain pattern 150 may include, for example, a binary or a ternary compound including at least two or more of carbon (C), silicon (Si), germanium (Ge), tin (Sn), or a compound of these doped with a group IV element. For example, the source/drain pattern 150 may include silicon (Si), silicon-germanium (SiGe), germanium (Ge), silicon carbide (SiC), etc., but is not limited thereto.

The source/drain pattern 150 may include impurities doped into a semiconductor material. The doped impurities may include at least one of boron (B), phosphorus (P), carbon (C), arsenic (As), antimony (Sb), bismuth (Bi), and/or oxygen (O), but aspects are not limited thereto.

Although it is illustrated that the source/drain pattern 150 is a single film, it is only for convenience of explanation, and aspects are not limited thereto. The source/drain pattern may include a plurality of films including different materials. In another aspect, the source/drain pattern may include a plurality of layers including the same material and having different concentrations of constituent materials.

The gate electrode 120 may extend on the substrate 100 in the second direction D2. The gate electrode 120 may cross the active pattern AP. The gate electrode 120 may be disposed on the lower pattern BP. The gate electrode 120 may be spaced apart from the adjacent gate electrode 120 in the first direction D1. The gate electrode 120 may surround the plurality of channel patterns CP. The gate electrode 120 may surround four surfaces of the channel pattern CP. For example, the gate electrode 120 may surround an upper surface, a lower surface, and both side surfaces of the channel pattern CP spaced apart in the second direction D2. The upper and lower surfaces of the channel pattern CP may refer to surfaces perpendicular to the third direction D3, and both side surfaces of the channel pattern CP may refer to surfaces perpendicular to the second direction D2.

The gate electrode 120 may include an upper gate electrode 120_U and the lower gate electrode 120_B. The lower gate electrode 120_B may be disposed between adjacent channel patterns CP in the third direction D3. The lower gate electrode 120_B may be disposed between the plurality of channel patterns CP, and may be disposed between the lower pattern BP and the channel pattern CP that is the lowermost one of the plurality of channel patterns CP. The upper gate electrode 120_U may be disposed on the channel pattern CP that is the uppermost one of the plurality of channel patterns CP.

According to some example embodiments, the active pattern AP may include a plurality of channel patterns CP, and the gate electrode 120 may include a plurality of lower gate electrodes 120_B. In this case, the number of the lower gate electrodes 120_B may be proportional to the number of channel patterns CP included in the active pattern AP. The number of the lower gate electrodes 120_B may be equal to the number of channel patterns CP. For example, as illustrated in FIG. 2, the number of lower gate electrodes 120_B may be 4, which may be the same as the number of channel patterns CP. However, aspects are not limited thereto.

The gate electrode 120 may include at least one of a metal, a metal alloy, a conductive metal nitride, a metal silicide, a doped semiconductor material, a conductive metal oxide, and/or a conductive metal oxynitride. For example, the gate electrode 120 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or a combination thereof, but is not limited thereto. The conductive metal oxide and the conductive metal oxynitride may include an oxidized form of the material described above, but is not limited thereto.

The insulating film structure 130 may be disposed between the gate electrode 120 and the plurality of channel patterns CP, between the gate electrode 120 and the lower pattern BP, and between the gate electrode 120 and the source/drain pattern 150. Specifically, the insulating film structure 130 may be disposed between the upper gate electrode 120_U and the channel pattern CP that is the uppermost one of the plurality of channel patterns CP. The insulating film structure 130 may be disposed between the lower gate electrode 120_B and the channel pattern CP. Furthermore, the insulating film structure 130 may be disposed between the inner gate spacer 140 and the source/drain pattern 150.

The insulating film structure 130 may extend in the first direction D1 along an upper surface and a lower surface of the channel pattern CP. The sidewall 130_SW of the insulating film structure 130 may extend in the third direction D3 along the sidewall 150_SW of the source/drain pattern 150. The sidewall 130_SW of the insulating film structure 130 may be defined as a portion in contact with the source/drain pattern 150. The sidewall 150_SW of the source/drain pattern 150 may be defined as a portion in contact with the insulating film structure 130 and the channel pattern CP. The sidewall 130_SW of the insulating film structure 130 may be disposed between the source/drain pattern 150 and the inner gate spacer 140. Specifically, the sidewall 130_SW of the insulating film structure 130 may include an outer surface in the direction of the source/drain pattern 150 and an inner surface in the direction of the inner gate spacer 140. The outer surface may be in contact with the source/drain pattern 150, and the inner surface may be in contact with the inner gate spacer 140. The sidewall 130_SW of the insulating film structure 130 may overlap the source/drain pattern 150 and the inner gate spacer 140 in the first direction D1. The insulating film structure 130 may surround the inner gate spacer 140 and the lower gate electrode 120_B.

The insulating film structure 130 may include an interfacial insulating film 132 and a high dielectric constant insulating film 134.

The interfacial insulating film 132 may extend in the first direction D1 along the upper and lower surfaces of the channel pattern CP and the upper surface of the lower pattern BP. The interfacial insulating film 132 may be in contact with the upper and lower surfaces of the channel pattern CP. The interfacial insulating film 132 may extend in the third direction D3 along the sidewall 150_SW of the source/drain pattern 150. The interfacial insulating film 132 may be in contact with the sidewall 150_SW of the source/drain pattern 150. It is illustrated that the interfacial insulating film 132 is disposed on the field insulating film 105, but aspects are not limited thereto. For example, the interfacial insulating film 132 may be disposed on the upper surface of the lower pattern BP, and may not be disposed on the field insulating film 105. In this case, the high dielectric constant insulating film 134 may be disposed on the field insulating film 105.

The thicknesses of the interfacial insulating film 132 extending in the first direction D1 and extending in the third direction D3 may be the same as each other. However, aspects are not limited thereto. The thicknesses of the interfacial insulating film 132 extending in the first direction D1 and the thickness of a portion of the interfacial insulating film 132 extending in the third direction D3 may be different from each other. The interfacial insulating film 132 may include silicon oxide.

The high dielectric constant insulating film 134 may be disposed on the interfacial insulating film 132. The high dielectric constant insulating film 134 may extend in the first direction D1 along the upper and lower surfaces of the channel pattern CP, the upper surface of the lower pattern BP, and the upper surface of the field insulating film 105. The high dielectric constant insulating film 134 may be disposed along the interfacial insulating film 132. The high dielectric constant insulating film 134 may be in contact with the inner gate spacer 140 and the lower gate electrode 120_B.

The thicknesses of the high dielectric constant insulating film 134 extending in the first direction D1 and extending in the third direction D3 may be the same as each other. However, aspects are not limited thereto. The thicknesses of the high dielectric constant insulating film 134 extending in the first direction D1 and the thickness of a portion of the high dielectric constant insulating film 134 extending in the third direction D3 may be different from each other.

The high dielectric constant insulating film 134 may include a high dielectric constant material having a higher dielectric constant than the interfacial insulating film 132. For example, the high dielectric constant insulating film 134 may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The inner gate spacer 140 will be described in detail with reference to FIG. 3. The inner gate spacer 140 may be disposed to be in contact with the lower gate electrode 120_B. The inner gate spacers 140 may be disposed on both sides of the lower gate electrode 120_B in the first direction D1. The inner gate spacer 140 may be disposed between the insulating film structure 130 and the gate electrode 120. Specifically, the inner gate spacer 140 may be disposed between the sidewall 130_SW of the insulating film structure 130 and the lower gate electrode 120_B.

The inner gate spacer 140 may be disposed between the lower gate electrode 120_B and the source/drain pattern 150. Accordingly, the source/drain pattern 150 may be spaced apart from the lower gate electrode 120_B at least by a length of the inner gate spacer 140 in the first direction D1.

The inner gate spacer 140 may extend in the second direction D2 along the lower gate electrode 120_B. For example, the inner gate spacer 140 may extend in the second direction D2 along the lower gate electrode 120_B in a portion of the lower gate electrode 120_B that overlaps the channel pattern CP in the third direction D3.

An upper surface 140_US, a lower surface 140_BS, and a first side surface 140_SS1 of the inner gate spacer 140 may be disposed on the insulating film structure 130. At least three surfaces of the inner gate spacer 140 may be in contact with the high dielectric constant insulating film 134. For example, the upper surface 140_US, the lower surface 140_BS, and the first side surface 140_SS1 of the inner gate spacer 140 may be in contact with the high dielectric constant insulating film 134.

A second side surface 140_SS2 opposite to the first side surface 140_SS1 of the inner gate spacer 140 may be disposed on the lower gate electrode 120_B. The second side surface 140_SS2 of the inner gate spacer 140 may be in contact with the lower gate electrode 120_B. The inner gate spacer 140 may be surrounded by the insulating film structure 130 and the lower gate electrode 120_B.

In some example embodiments, the second side surface 140_SS2 of the inner gate spacer 140 may be parallel to the third direction D3. That is, the surface on which the inner gate spacer 140 is in contact with the lower gate electrode 120_B may be parallel to the third direction D3. However, aspects are not limited thereto.

The first side surface 140_SS1 of the inner gate spacer 140 may be in contact with the sidewall 130_SW of the insulating film structure 130. The sidewall 130_SW of the insulating film structure 130 may be disposed between the source/drain pattern 150 and the inner gate spacer 140. The insulating film structure 130 may be disposed on the upper surface 140_US and the lower surface 140_BS of the inner gate spacer 140. The insulating film structure 130 may be disposed between the upper surface 140_US of the inner gate spacer 140 and the channel pattern CP, and between the lower surface 140_BS of the inner gate spacer 140 and the channel pattern CP. The inner gate spacer 140 may overlap the insulating film structure 130 in the third direction D3.

For example, the inner gate spacer 140 may include at least one of silicon oxide (SiO), silicon nitride oxide (SiON), silicon boron nitride (SiBN), silicon oxycarbonitride (SiOCN), and/or silicon nitride (SiN). In some example embodiments, the inner gate spacer 140 may not include germanium (Ge).

According to some example embodiments, the inner gate spacer 140 may be disposed between the gate electrode 120 and the source/drain pattern 150, which can reduce a capacitance value between the gate electrode 120 and the source/drain pattern 150. Accordingly, the performance of the semiconductor device can be improved.

According to some example embodiments, the insulating film structure 130 may be disposed between the inner gate spacer 140 and the channel pattern CP, which may prevent or reduce in likelihood the constituent material (e.g., nitrogen (N) component) of the inner gate spacer 140 from diffusing into the channel pattern CP during the manufacturing process. Accordingly, the reliability of the semiconductor device may be improved.

In some example embodiments, as illustrated in FIG. 4, the second side surface 140_SS2 of the inner gate spacer 140 may have a convex shape toward the source/drain pattern 150. For example, the second side surface 140_SS2 of the inner gate spacer 140 may have a concave shape toward the source/drain pattern 150. A width of the inner gate spacer 140 in the first direction D1 may gradually decrease from the upper surface 140_US of the inner gate spacer 140 toward the center and gradually increase from the center toward the lower surface 140_BS. The center of the inner gate spacer 140 may refer to an intermediate portion between the upper surface 140_US and the lower surface 140_BS in the third direction D3.

Referring to FIGS. 1 to 5 again, the gate spacer 160 may be disposed on the side surfaces of the upper gate electrode 120_U and a gate capping pattern 165. For example, the gate spacer 160 may extend along a side surface of the upper gate electrode 120_U and a side surface of the gate capping pattern 165. The gate spacer 160 may not be positioned between the lower pattern BP and the channel pattern CP. The gate spacer 160 may not be positioned between the adjacent channel patterns CP in the third direction D3.

For example, the gate spacer 160 may include at least one of silicon nitride (SiN), silicon nitride oxide (SiON), silicon oxide (SiO₂), silicon carbonate (SiOCN), silicon boron nitride (SiBN), silicon boron oxide (SiOBN), silicon oxycarbide (SiOC), and/or a combination thereof. Although it is illustrated that the gate spacer 160 is a single film, it is only for convenience of description, and aspects are not limited thereto.

In some example embodiments, the insulating film structure 130 may be disposed between the upper gate electrode 120_U and the channel pattern CP, and may not be disposed on the gate spacer 160. For example, the insulating film structure 130 may not be disposed between the gate spacer 160 and the upper gate electrode 120_U nor between the gate spacer 160 and the gate capping pattern 165. However, aspects are not limited thereto.

The gate capping pattern 165 may be disposed on the upper gate electrode 120_U. The gate capping pattern 165 may cover an upper surface of the upper gate electrode 120_U. The gate capping pattern 165 may overlap the upper gate electrode 120_U in the third direction D3. The gate capping pattern 165 may be disposed between the gate spacers 160. The side surface of the gate capping pattern 165 may be in contact with the gate spacer 160. The upper surface of the gate capping pattern 165 may be in flush with the upper surface of an interlayer insulating film 180. However, aspects are not limited thereto.

It is illustrated that the width of the gate capping pattern 165 in the first direction D1 is the same as the width of the upper gate electrode 120_U in the first direction D1, but aspects are not limited thereto. For example, the width of the gate capping pattern 165 in the first direction D1 may be greater than the width of the upper gate electrode 120_U in the first direction D1. In this case, the gate capping pattern 165 may be disposed on the upper surface of the upper gate electrode 120_U and the upper surface of the gate spacer 160.

For example, the gate capping pattern 165 may include at least one of silicon nitride (SiN), silicon oxynitride (SiON), silicon carbon nitride (SiCN), silicon oxycarbonitride (SiOCN), and/or a combination thereof. The gate capping pattern 165 may include a material having etch selectivity with respect to the interlayer insulating film 180.

An etching stop film 170 may extend along the profile of a sidewall of the gate spacer 160 and an upper surface of the source/drain pattern 150. Although not illustrated, the etching stop film 170 may be disposed on an upper surface of the field insulating film 105.

The etching stop film 170 may include a material having an etching selectivity with respect to the interlayer insulating film 180. For example, the etching stop film 170 may include at least one of silicon nitride (SiN), silicon oxide (SiO), silicon oxynitride (SiON), silicon oxycarbonitride (SiOCN), silicon boron nitride (SiBN), silicon oxyboron nitride (SiOBN), silicon oxycarbide (SiOC), and/or a combination thereof.

The interlayer Insulating film 180 may be disposed on the etching stop film 170. The interlayer insulating film 180 may be disposed on the source/drain pattern 150. The interlayer insulating film 180 may be disposed on one side of the upper gate electrode 120_U. The interlayer insulating film 180 may be disposed between the upper gate electrodes 120_U.

For example, the interlayer insulating film 180 may include at least one of silicon oxide (SiO), silicon nitride (SiN), silicon oxynitride (SiON), and/or a low dielectric constant material. For example, the low dielectric constant material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but is not limited thereto.

Although not illustrated, the semiconductor device according to some example embodiments may further include a source/drain contact. The source/drain contact may be disposed on the source/drain pattern 150. The source/drain contact may extend through the interlayer insulating film 180 and the etching stop film 170. The source/drain contact may be connected to the source/drain pattern 150.

The source/drain contact may include a conductive material. For example, the source/drain contact may include at least one of a metal, a metal nitride, a metal carbon nitride, a two-dimensional (2D) material, and/or a conductive semiconductor material.

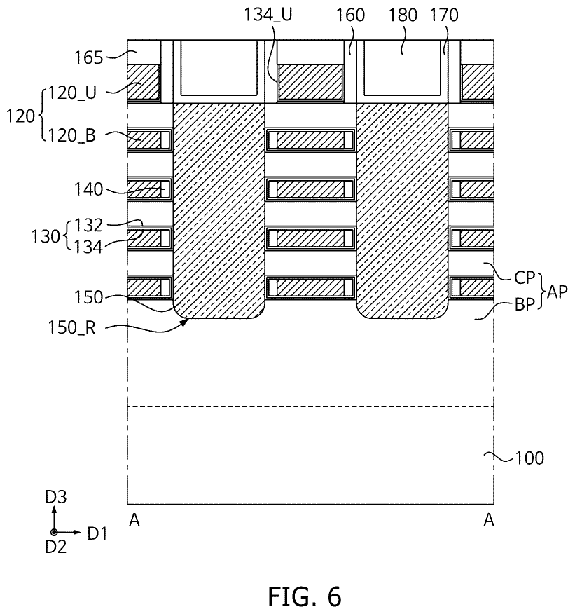

FIG. 6 is a diagram illustrating a semiconductor device according to some example embodiments of the present disclosure. For convenience of explanation, different configurations from those described with reference to FIGS. 1 to 5 will be mainly described. Referring to FIG. 6, in a semiconductor device according to some example embodiments, the insulating film structure 130 may include the interfacial insulating film 132, the high dielectric constant insulating film 134, and an upper high dielectric constant insulating film 134_U. The interfacial insulating film 132 and the high dielectric constant insulating film 134 may be the same as described above.

The upper high dielectric constant insulating film 134_U may be disposed between the upper gate electrode 120_U and the gate spacer 160. The upper high dielectric constant insulating film 134_U may extend along the side surface of the upper gate electrode 120_U. The upper high dielectric constant insulating film 134_U may not be disposed between the gate capping pattern 165 and the gate spacer 160. The upper high dielectric constant insulating film 134_U may extend in the third direction D3 from the high dielectric constant insulating film 134 disposed between the upper gate electrode 120_U and the channel pattern CP. The upper high dielectric constant insulating film 134_U may include the same material as the high dielectric constant insulating film 134.

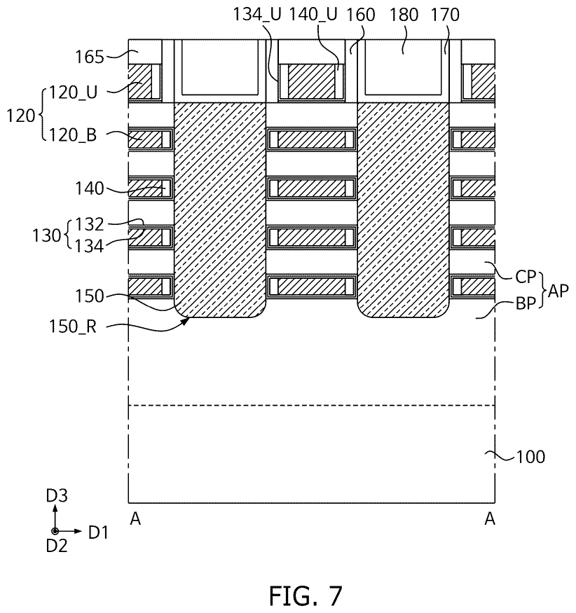

FIG. 7 is a diagram illustrating a semiconductor device according to some example embodiments of the present disclosure. For convenience of explanation, different configurations from those described with reference to FIGS. 1 to 6 will be mainly described.

Referring to FIG. 7, a semiconductor device according to some example embodiments may further include an upper inner gate spacer 140_U.

The upper inner gate spacer 140_U may be disposed on the side surface of the upper gate electrode 120_U. The upper inner gate spacer 140_U may be disposed between the upper gate electrode 120_U and the upper high dielectric constant insulating film 134_U. The upper inner gate spacer 140_U may extend along the side surface of the upper gate electrode 120_U. The upper inner gate spacer 140_U may not be disposed between the gate capping pattern 165 and the gate spacer 160.

The upper inner gate spacer 140_U may include the same material as the inner gate spacer 140. A thickness of the upper inner gate spacer 140_U in the first direction D1 may be different from a thickness of the inner gate spacer 140 in the first direction D1. For example, the thickness of the upper inner gate spacer 140_U in the first direction D1 may be smaller than the thickness of the inner gate spacer 140 in the first direction D1. However, aspects are not limited thereto. The thickness of the upper inner gate spacer 140_U in the first direction D1 may be the same as the thickness of the inner gate spacer 140 in the first direction D1.

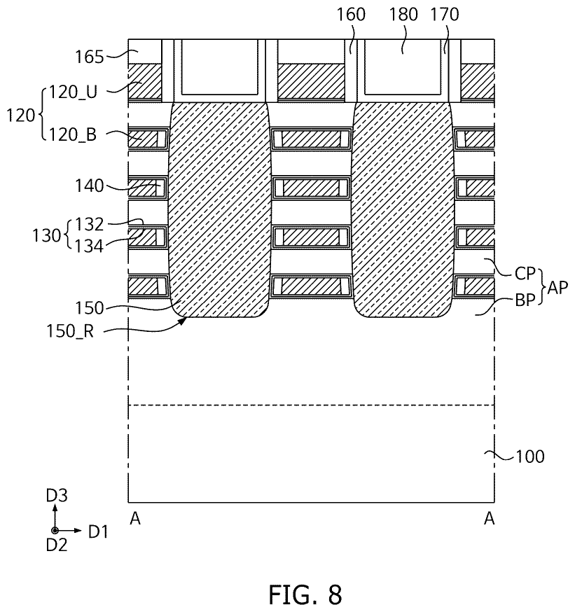

FIG. 8 is a diagram illustrating a semiconductor device according to some example embodiments of the present disclosure. For convenience of explanation, different configurations from those described with reference to FIGS. 1 to 5 will be mainly described.

Referring to FIG. 8, in the semiconductor device according to some example embodiments, a width of the source/drain pattern 150 in the first direction D1 may not be constant.

For example, the width of the source/drain pattern 150 in the first direction D1 may increase and then decrease as the distance from the substrate 100 increases. The sidewall 150_SW of the source/drain pattern 150 may have a convex shape toward the channel pattern CP.

The width of each of the channel patterns CP in the first direction D1 may be different. For example, the width of the channel pattern CP that is the uppermost one of the plurality of channel patterns CP may be greater than the width of the adjacent channel pattern CP in the third direction D3. The width of the lowermost channel pattern CP of the plurality of channel patterns CP may be greater than the width of the adjacent channel pattern CP in the third direction D3.

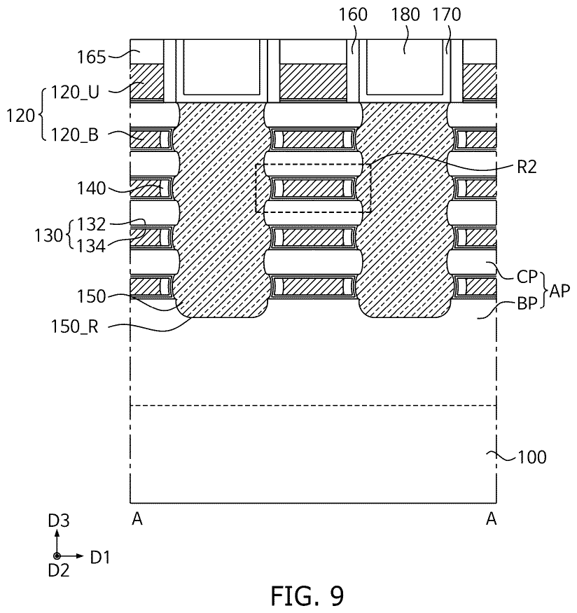

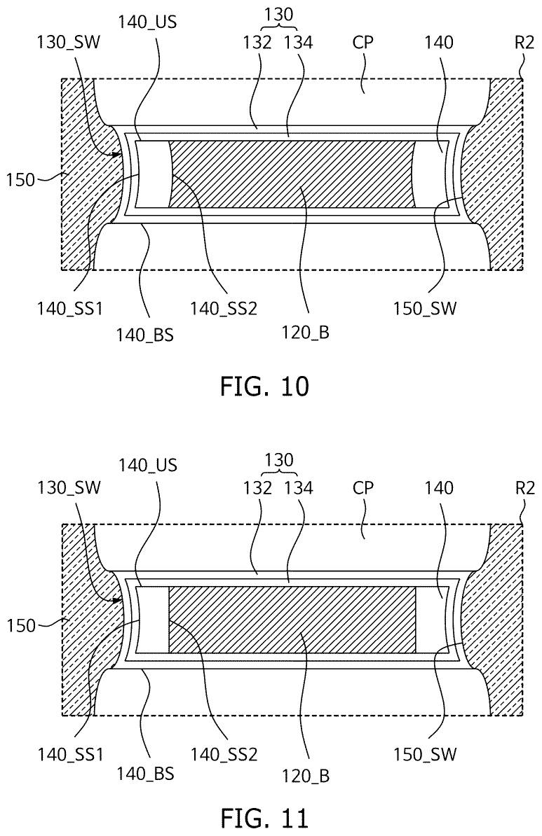

FIG. 9 is a diagram illustrating a semiconductor device according to some example embodiments of the present disclosure. FIGS. 10 and 11 are enlarged views provided to explain a region R2 of FIG. 9. For convenience of explanation, different configurations from those described with reference to FIGS. 1 to 5 will be mainly described.

Referring to FIGS. 9 to 11, in the semiconductor device according to some example embodiments, the sidewall 150_SW of the source/drain pattern 150 may have a wavy shape.

For example, the width of the source/drain pattern 150 may be repeatedly decreased and increased in the first direction D1. The width of the source/drain pattern 150 in the first direction D1 at a portion adjacent to the channel pattern CP may be less than the width of the source/drain pattern 150 in the first direction D1 at a portion adjacent to the inner gate spacer 140. The source/drain pattern 150 may include a protruding portion extending toward the insulating film structure 130. The protruding portion of the source/drain pattern 150 may overlap the insulating film structure 130 in the first direction D1.

An exterior surface of the sidewall 130_SW of the insulating film structure 130 may be in contact with the source/drain pattern 150. An interior surface of the sidewall 130_SW of the insulating film structure 130 may have a convex shape toward the lower gate electrode 120_B. For example, an exterior surface of the sidewall 130_SW of the insulating film structure 130 may have a concave shape toward the lower gate electrode 120_B. The inner gate spacer 140 may be disposed on the interior surface of the sidewall 130_SW of the insulating film structure 130. The first side surface 140_SS1 of the inner gate spacer 140 may be in contact with the insulating film structure 130. The second side surface 140_SS2 of the inner gate spacer 140 may be in contact with the lower gate electrode 120_B. The first side surface 140_SS1 of the inner gate spacer 140 may have a concave shape toward the lower gate electrode 120_B. As illustrated in FIG. 10, the second side surface 140_SS2 of the inner gate spacer 140 may have a convex shape toward the lower gate electrode 120_B. In another aspect, as illustrated in FIG. 11, the second side surface 140_SS2 of the inner gate spacer 140 may have a flat shape. The second side surface 140_SS2 of the inner gate spacer 140 may be parallel to the third direction D3.

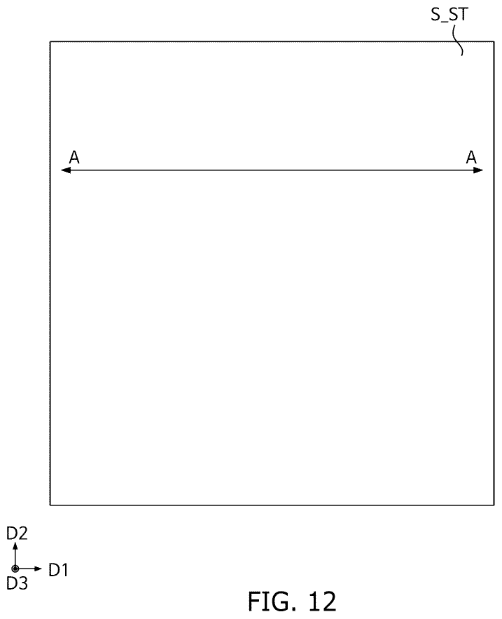

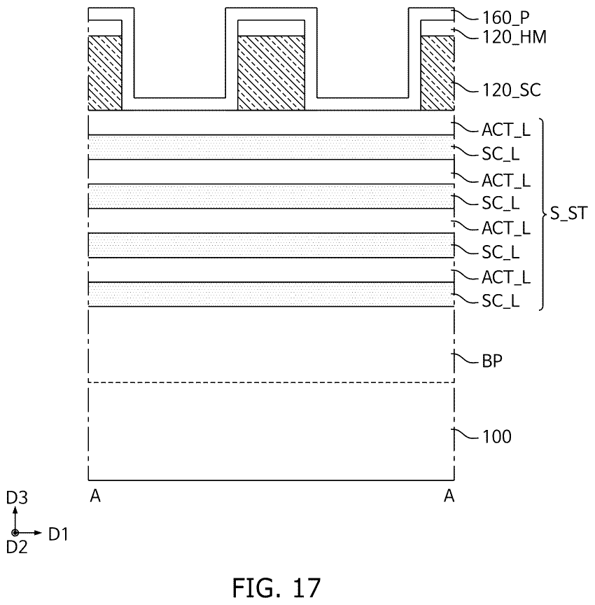

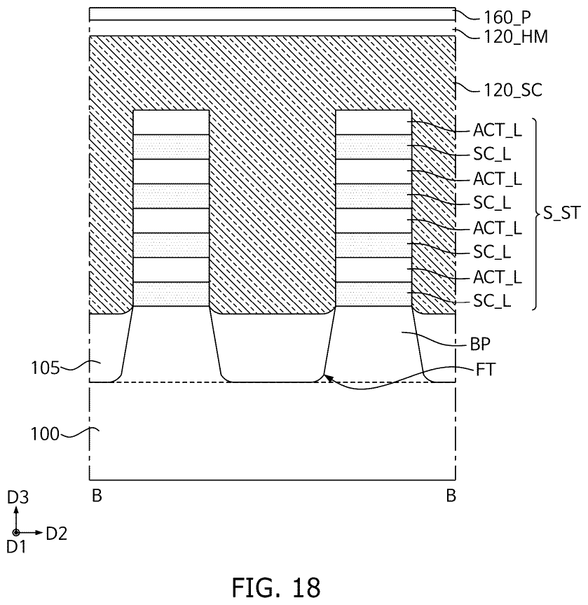

FIGS. 12 to 30 are diagrams showing intermediate stages, provided to explain some methods for manufacturing semiconductor devices according to some example embodiments of the present disclosure.

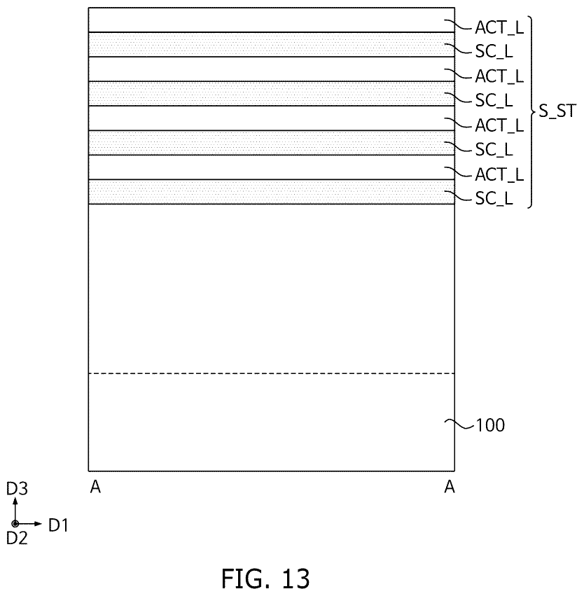

Referring to FIGS. 12 and 13, the method for manufacturing the semiconductor device according to some example embodiments may include forming a stacked structure S_ST on the substrate 100.

The substrate 100 may be a silicon substrate, or may include other materials, such as silicon germanium (SiGe), silicon germanium on insulator (SGOI), indium antimony, lead tellurium compound, indium arsenic, indium phosphide, gallium arsenic, or gallium antimony, but is not limited thereto.

The stacked structure S_ST may be formed on the substrate 100. The stacked structure S_ST may include a sacrificial semiconductor layer SC_L and an active semiconductor layer ACT_L, which may be alternately stacked. The sacrificial semiconductor layer SC_L may be disposed on the lowermost portion of the stacked structure S_ST. The active semiconductor layer ACT_L may be disposed on the uppermost side of the stacked structure S_ST. The active semiconductor layer ACT_L and the sacrificial semiconductor layer SC_L may be formed of materials having different etching selectivities.

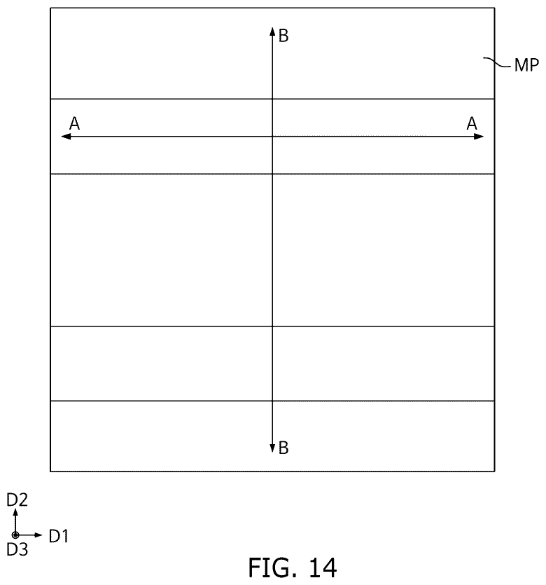

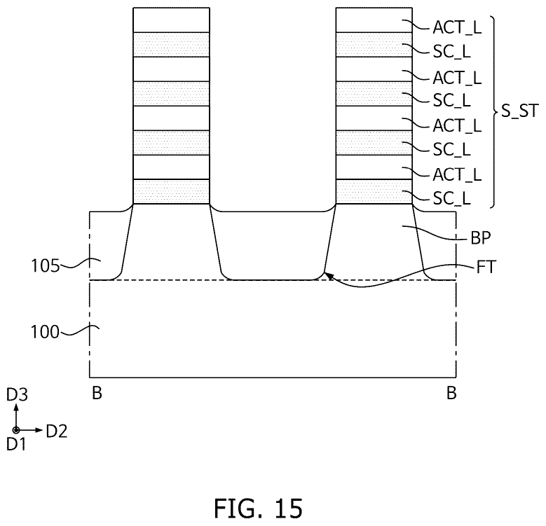

Referring to FIGS. 14 and 15, a mask pattern MP may be formed on the stacked structure S_ST, and using the mask pattern MP as a mask, the stacked structure S_ST may be patterned, that is, selectively removed. Specifically, the mask pattern MP may expose a part of an upper surface of the stacked structure S_ST. Using the mask pattern MP, the stacked structure S_ST may be patterned to form the field trench FT and the lower pattern BP. The patterned stacked structures S_ST may be spaced apart from each other in the second direction D2.

The field insulating film 105 may be formed on the field trench FT. The field insulating film 105 may fill the field trench FT. It is illustrated that the field insulating film 105 is a single film, but aspects are not limited thereto.

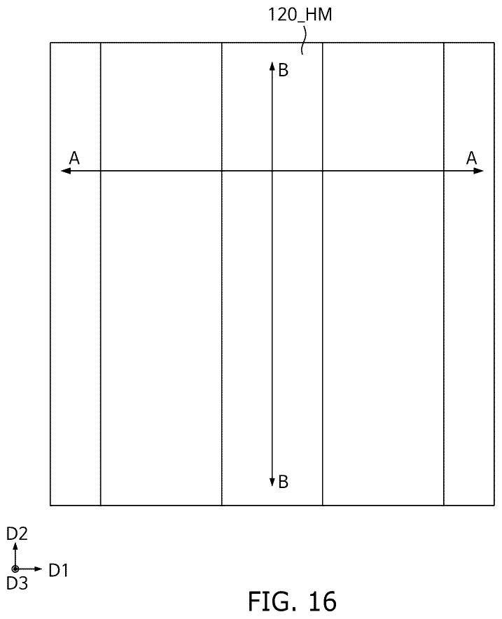

Referring to FIGS. 16 to 18, a gate sacrificial pattern 120_SC and a hard mask pattern 120_HM may be formed on the stacked structure S_ST and the field insulating film 105, and a pre-liner layer 160_P may be formed on the hard mask pattern 120_HM and the stacked structure S_ST.

Specifically, polysilicon may be formed on the stacked structure S_ST. In addition, using the hard mask pattern 120_HM as a mask, polysilicon may be patterned to form the gate sacrificial pattern 120_SC. The hard mask pattern 120_HM on the gate sacrificial pattern 120_SC may not be removed. The gate sacrificial pattern 120_SC may extend in the second direction D2. The gate sacrificial pattern 120_SC may cross the stacked structure S_ST.

The pre-liner layer 160_P may be formed on the hard mask pattern 120_HM and the stacked structure S_ST. The pre-liner layer 160_P may be formed along the hard mask pattern 120_HM, a side surface of the gate sacrificial pattern 120_SC, and the upper surface of the stacked structure S_ST.

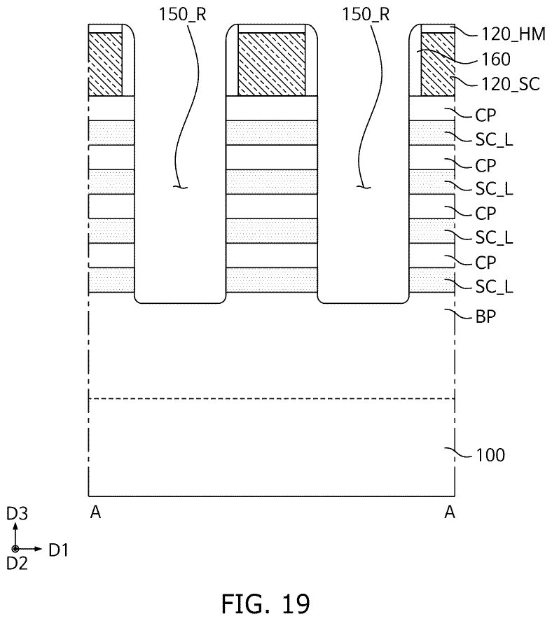

Referring to FIG. 19, a source/drain trench 150_R may be formed in the stacked structure S_ST using an etching process. The active semiconductor layer ACT_L may be separated by the source/drain trench 150_R to form the channel pattern CP.

Specifically, etching process may be performed on the pre-liner layer 160_P to form the source/drain trench 150_R. The source/drain trench 150_R may expose the channel pattern CP and the sacrificial semiconductor layer SC_L. While the etching process is being performed, the thickness of the hard mask pattern 120_HM in the third direction D3 may decrease. In addition, a part of the pre-liner layer 160_P may be removed to form the gate spacer 160.

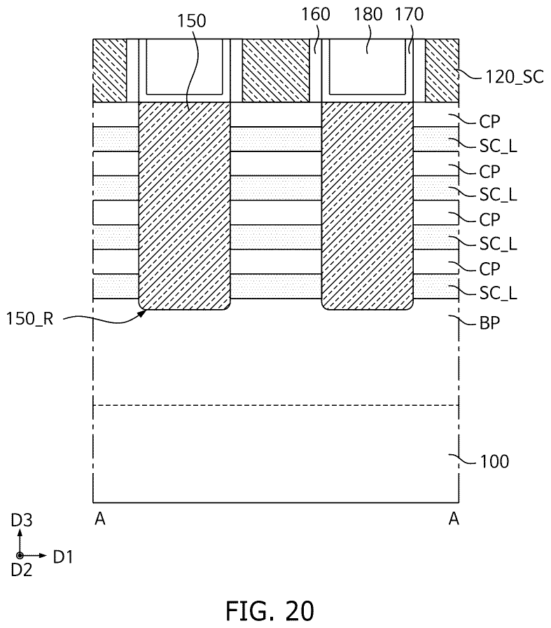

Referring to FIG. 20, the source/drain pattern 150 may be formed in the source/drain trench 150_R, and the etching stop film 170 and the interlayer insulating film 180 may be formed on the source/drain pattern 150.

Specifically, the source/drain pattern 150 may be formed using an epitaxial growth method. Sidewalls of the lower pattern BP and the channel pattern CP exposed by the source/drain trench 150_R may be used as a seed. It is illustrated that the source/drain pattern 150 is a single layer, but it may include a plurality of layers.

In some example embodiments, the source/drain pattern 150 may be formed using at least one of low-pressure chemical vapor deposition (LPCVD) process, selective epitaxial growth (SEG) process, or cyclic deposition and etching (CDE) process by using raw materials including an elemental semiconductor precursor.

The etching stop film 170 and the interlayer insulating film 180 may be formed on the upper surface of the source/drain pattern 150. The etching stop film 170 may be formed along the upper surface of the source/drain pattern 150 and a side surface of the gate spacer 160. The interlayer insulating film 180 may be formed on the etching stop film 170.

Specifically, the interlayer insulating film 180 may be formed to cover the hard mask pattern 120_HM, the gate spacer 160, and the etching stop film 170. The hard mask pattern 120_HM may be removed through a planarization process, and the gate sacrificial pattern 120_SC may be exposed. Accordingly, the upper surface of the gate sacrificial pattern 120_SC and the upper surface of the interlayer insulating film 180 may be in flush with each other. For example, the planarization process may be the chemical mechanical polishing (CMP) process.

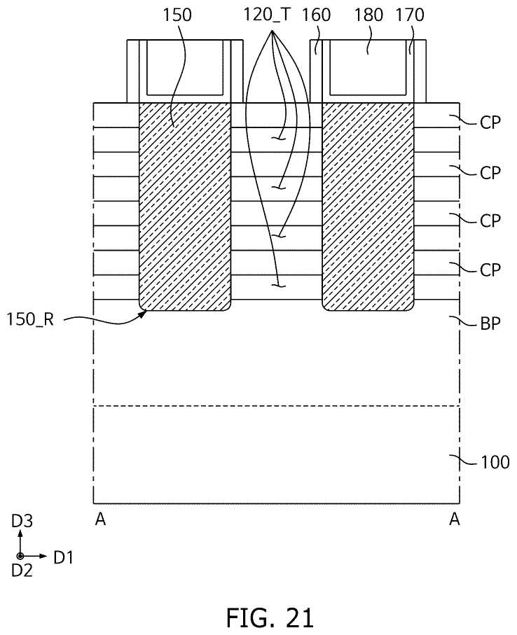

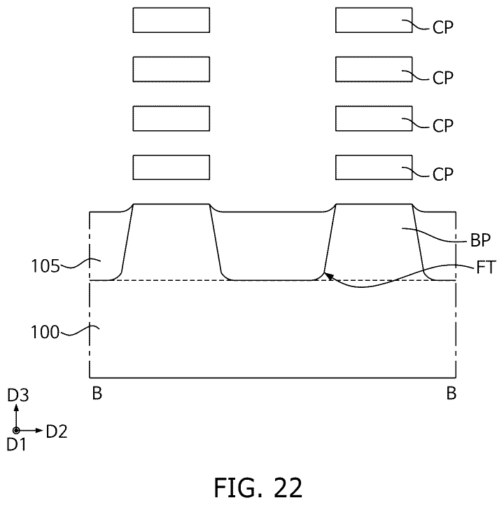

Referring to FIGS. 21 and 22, the gate sacrificial pattern 120_SC may be removed, and the sacrificial semiconductor layer SC_L may be removed to form a gate trench 120_T. The gate trench 120_T may expose the channel pattern CP and the source/drain pattern 150.

In order to remove the sacrificial semiconductor layer SC_L, difference in the etching selectivity between the sacrificial semiconductor layer SC_L and the channel pattern CP may be used. A liquid or gaseous etchant may be used to selectively remove the sacrificial semiconductor layer SC_L.

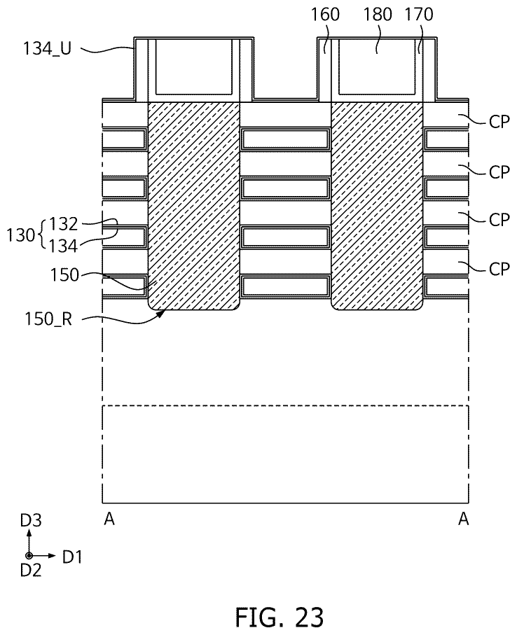

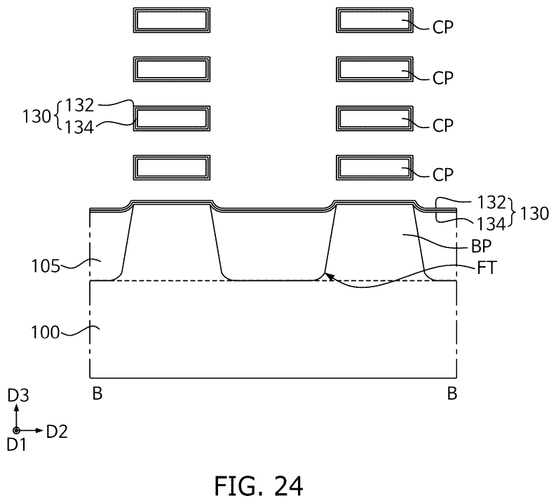

Referring to FIGS. 23 and 24, the insulating film structure 130 may be formed in the gate trench 120_T and on the channel pattern CP, the gate spacer 160, and the interlayer insulating film 180. The insulating film structure 130 may include the interfacial insulating film 132, the high dielectric constant insulating film 134, and the upper high dielectric constant insulating film 134_U.

Specifically, after the formation of the interfacial insulating film 132, the high dielectric constant insulating film 134 may be formed. The interfacial insulating film 132 may be formed along the exposed channel pattern CP and the source/drain pattern 150. The interfacial insulating film 132 may cover the channel pattern CP. The interfacial insulating film 132 may not be formed on the sidewall of the gate spacer 160.

The high dielectric constant insulating film 134 may be formed along the profile of the interfacial insulating film 132. The upper high dielectric constant insulating film 134_U may be formed on the side surface of the gate spacer 160. The high dielectric constant insulating film 134 and the upper high dielectric constant insulating film 134_U may be formed by the same process. For example, the high dielectric constant insulating film 134 and the upper high dielectric constant insulating film 134_U may be formed using the atomic layer deposition (ALD) process.

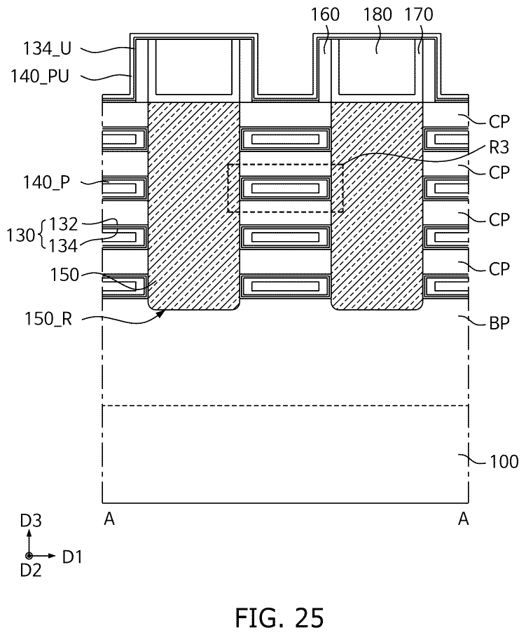

Referring to FIGS. 25 to 27, a pre-inner gate spacer 140_P and an upper pre-inner gate spacer 140_PU may be formed on the insulating film structure 130.

The upper pre-inner gate spacer 140_PU may be formed on the uppermost channel pattern CP, the gate spacer 160, and the interlayer insulating film 180. The upper pre-inner gate spacer 140_PU may be formed along the upper high dielectric constant insulating film 134_U.

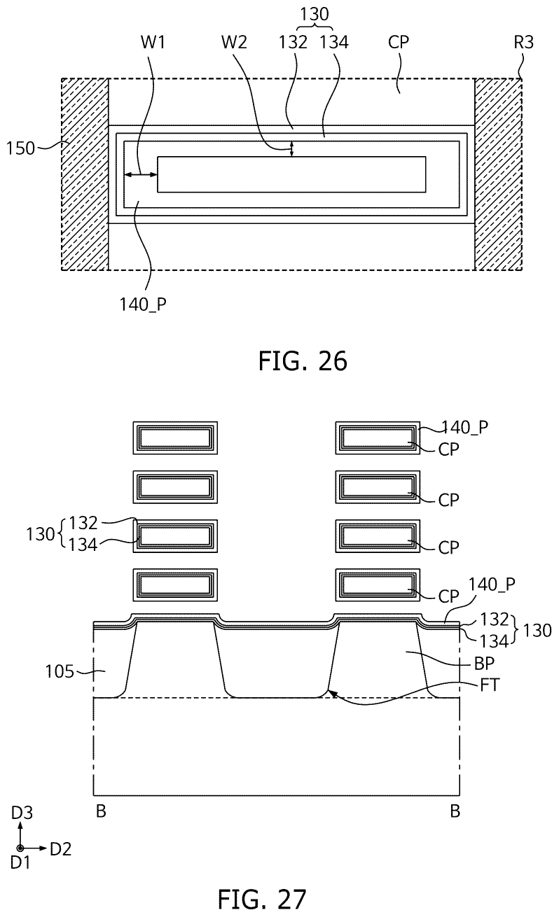

The pre-inner gate spacer 140_P may be formed along the insulating film structure 130 disposed between the channel pattern CP and the adjacent channel pattern CP. The pre-inner gate spacer 140_P may fill a part of a space in the insulating film structure 130. The thicknesses of the pre-inner gate spacer 140_P in the first direction D1 and the third direction D3 may be different according to the aspect ratio of the space in the insulating film structure 130. As illustrated in FIG. 26, a width W1 of the pre-inner gate spacer 140_P in the first direction D1 may be greater than a width W2 in the third direction D3.

For example, the pre-inner gate spacer 140_P and the upper pre-inner gate spacer 140_PU may be formed using the chemical vapor deposition (CVD) and atomic layer deposition (ALD) processes. However, aspects are not limited thereto.

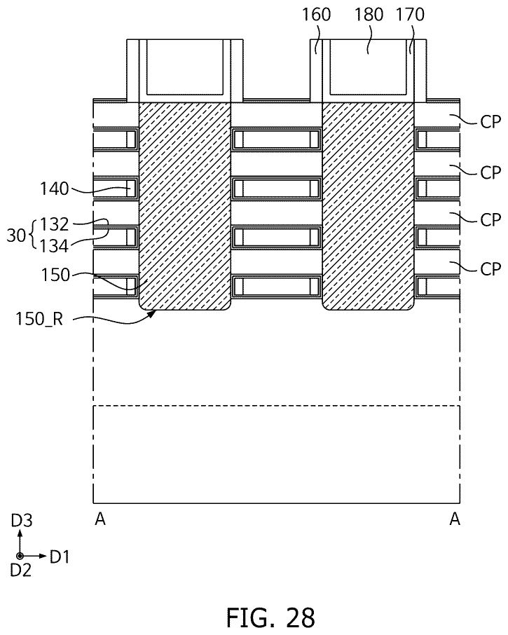

Referring to FIG. 28, a part of the pre-inner gate spacer 140_P may be removed to form the inner gate spacer 140.

Specifically, the upper pre-inner gate spacer 140_PU and the pre-inner gate spacer 140_P may be partially removed using a wet etching process. By the wet etching process, the pre-inner gate spacer 140_P may be isotropically etched. Since the width W1 of the pre-inner gate spacer 140_P in the first direction D1 is greater than the width W2 in the third direction D3, when all the pre-inner gate spacers 140_P having the thickness in the third direction D3 are removed, the pre-inner gate spacer 140_P having the thickness in the first direction D1 may remain. Accordingly, the inner gate spacer 140 may be formed, and the insulating film structure 130 may be exposed.

The upper pre-inner gate spacer 140_PU may be completely removed by the wet etching process. In this case, the upper high dielectric constant insulating film 134_U may also be removed. However, aspects are not limited thereto. For example, as illustrated in FIG. 6, the upper high dielectric constant insulating film 134_U may not be removed. In addition, as illustrated in FIG. 7, a part of the upper pre-inner gate spacer 140_PU may be removed, and the upper inner gate spacer 140_U may be formed.

In some example embodiments, the pre-inner gate spacer 140_P may be removed by the wet etching process after oxidation process. For example, a part of the pre-inner gate spacer 140_P may be oxidized in an oxygen (O₂) atmosphere. The oxidized pre-inner gate spacer may be removed using the etch selectivities of the pre-inner gate spacer 140_P and the oxidized pre-inner gate spacer.

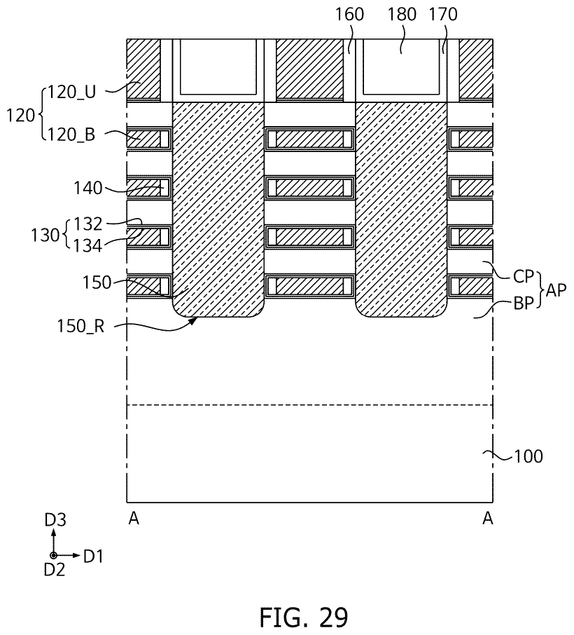

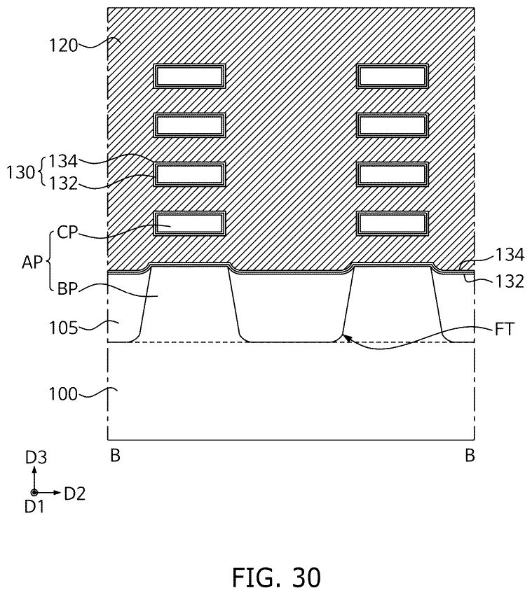

Referring to FIGS. 29 and 30, the gate electrode 120 may be formed on the insulating film structure 130. The gate electrode 120 may surround the channel pattern CP. The gate electrode 120 may extend in the second direction D2. The gate electrode 120 may include the upper gate electrode 120_U and the lower gate electrode 120_B.

Specifically, the upper gate electrode 120_U may be formed on the gate spacer 160. The upper gate electrode 120_U may fill a space between the gate spacer 160 and the adjacent gate spacer 160. The lower gate electrode 120_B may be formed on the insulating film structure 130. The lower gate electrode 120_B may fill a space between the channel pattern CP and the adjacent channel pattern CP.

The capacitance in the field effect transistor (FET) may reduce the performance of the semiconductor device. For example, as the distance between the gate electrode and the source/drain pattern decreases, the capacitance may be formed between the gate electrode and the source/drain pattern. In order to reduce this capacitance, the inner gate spacer may be formed between the gate electrode and the source/drain pattern. However, if the inner gate spacer and the silicon channel are in contact with each other, some of the constituent materials of the inner gate spacer may diffuse into the silicon channel, which may degrade the performance of the semiconductor device.

On the other hand, according to the semiconductor device according to some example embodiments of the present disclosure, the inner gate spacer 140 may be disposed between the source/drain pattern 150 and the lower gate electrode 120_B, thereby reducing the capacitance value between the source/drain pattern 150 and the gate electrode 120. In addition, the insulating film structure 130 may be disposed between the inner gate spacer 140 and the channel pattern CP, and the inner gate spacer 140 may be formed after the insulating film structure 130, thereby preventing or reducing in likelihood the constituent materials (e.g., nitrogen (N) component) of the inner gate spacer 140 from diffusing into the channel pattern CP. Accordingly, the performance and reliability of the semiconductor device can be improved.

As illustrated in FIGS. 2 and 3, the gate capping pattern 165 may be formed on the upper gate electrode 120_U. For example, a part of the upper gate electrode 120_U may be recessed and the gate capping pattern 165 may be formed on the upper surface of the upper gate electrode 120_U.

Although the present disclosure has been described above with respect to some example embodiments thereof, the present disclosure is not limited thereto. Various modifications and variations can be made thereto by those skilled in the art within the spirit of the present disclosure and the equivalent scope of the appended claims.

The invention claimed is:

1. A semiconductor device comprising:
a substrate;
an active pattern on the substrate, the active pattern including a plurality of channel patterns spaced apart from each other and vertically stacked on each other;
a source/drain pattern on at least one side of the plurality of channel patterns;
a gate electrode surrounding the plurality of channel patterns, the gate electrode including a lower gate electrode between adjacent channel patterns of the plurality of channel patterns;
an insulating film structure between the gate electrode and the plurality of channel patterns; and
an inner gate spacer between the source/drain pattern and the lower gate electrode,
wherein a sidewall of the insulating film structure is between the source/drain pattern and the inner gate spacer.

2. The semiconductor device according to claim 1, wherein the inner gate spacer is surrounded by the insulating film structure and the lower gate electrode.

3. The semiconductor device according to claim 1, wherein a part of the insulating film structure extends along the source/drain pattern and contacts the source/drain pattern.

4. The semiconductor device according to claim 1, wherein
a first side surface of the inner gate spacer is in contact with the sidewall of the insulating film structure, and
a second side surface of the inner gate spacer opposite to the first side surface is in contact with the lower gate electrode.

5. The semiconductor device according to claim 4, wherein the second side surface of the inner gate spacer has a convex shape toward the source/drain pattern.

6. The semiconductor device according to claim 1, wherein
the insulating film structure includes an interfacial insulating film on the plurality of channel patterns, and
a high dielectric constant insulating film between the inner gate spacer and the interfacial insulating film.

7. The semiconductor device according to claim 6, wherein at least three surfaces of the inner gate spacer are in contact with the high dielectric constant insulating film.

8. The semiconductor device according to claim 1, wherein the inner gate spacer includes at least one of silicon oxide, silicon nitride oxide, silicon boron nitride, silicon oxycarbonitride, or silicon nitride.

9. The semiconductor device according to claim 1, wherein the gate electrode further includes an upper gate electrode on the plurality of channel patterns, and
a gate capping pattern on the upper gate electrode.

10. The semiconductor device according to claim 9, further comprising:
a gate spacer on one side of the upper gate electrode,
wherein a part of the insulating film structure is between the gate spacer and the upper gate electrode.

11. The semiconductor device according to claim 10, further comprising:
an upper inner gate spacer between the upper gate electrode and the gate spacer.

12. The semiconductor device according to claim 1, wherein a sidewall of the source/drain pattern has a wavy shape.

13. A semiconductor device comprising:
a substrate;
an active pattern extending in a first direction, the active pattern including a lower pattern on the substrate and a plurality of channel patterns spaced apart in a second direction perpendicular to the first direction;
a source/drain pattern on at least one side of the plurality of channel patterns;
a gate electrode surrounding the plurality of channel patterns and extending in a third direction crossing the second direction, the gate electrode including
an upper gate electrode on the plurality of channel patterns, and
a lower gate electrode between adjacent channel patterns of the plurality of channel patterns;
an insulating film structure between the gate electrode and the plurality of channel patterns and between the gate electrode and the source/drain pattern; and
an inner gate spacer extending in the third direction and between the lower gate electrode and the source/drain pattern,
wherein the insulating film structure is between an upper surface of the inner gate spacer and the plurality of channel patterns.

14. The semiconductor device according to claim 13, wherein
the insulating film structure includes an interfacial insulating film on the plurality of channel patterns, and
a high dielectric constant insulating film on the interfacial insulating film.

15. The semiconductor device according to claim 14, wherein the interfacial insulating film is in contact with the plurality of channel patterns and the source/drain pattern.

16. The semiconductor device according to claim 14, wherein the high dielectric constant insulating film is in contact with the upper surface, a lower surface, and a first side surface of the inner gate spacer.

17. The semiconductor device according to claim 13, further comprising:
a gate spacer on at least one side of the upper gate electrode,
wherein the upper gate electrode is in contact with the gate spacer.

18. The semiconductor device according to claim 14, wherein a first side surface of the inner gate spacer is in contact with the high dielectric constant insulating film and has a concave shape toward the lower gate electrode.

19. The semiconductor device according to claim 18, wherein a second side surface of the inner gate spacer opposite to the first side surface is in contact with the lower gate electrode and is parallel to the second direction.

20. A semiconductor device comprising:
a substrate;
an active pattern extending in a first direction, the active pattern including a lower pattern on the substrate and a plurality of channel patterns spaced apart in a second direction perpendicular to the first direction;
a source/drain pattern on at least one side of the plurality of channel patterns;
a gate electrode surrounding the plurality of channel patterns, the gate electrode including an upper gate electrode on the plurality of channel patterns, and a lower gate electrode between adjacent channel patterns of the plurality of channel patterns;
a gate spacer on one side of the upper gate electrode;
an insulating film structure between the gate electrode and the plurality of channel patterns, the insulating film structure including an interfacial insulating film on the plurality of channel patterns and a high dielectric constant insulating film on the interfacial insulating film; and
an inner gate spacer between the insulating film structure and the lower gate electrode,
wherein a sidewall of the insulating film structure is between the source/drain pattern and the inner gate spacer, and
the high dielectric constant insulating film is in contact with an upper surface, a lower surface, and a side surface of the inner gate spacer, respectively.
